(19) United States
(12) Patent Application Publication
(10) Pub. No.: US 2007/0176271 A1
(43) Pub. Date: Aug. 2, 2007

(54) INTEGRATED CIRCUIT PACKAGE SYSTEM HAVING DIE-ATTACH PAD WITH ELEVATED BONDLINE THICKNESS

(75) Inventors: Arnel Trasporto, Singapore (SG); Henry D. Bathan, Singapore (SG); Zigmund Ramirez Camacho, Singapore (SG); Jeffrey D. Punzalan, Singapore (SG)

Correspondence Address: ISHIMARU & ZAHRT LLP, 333 W. EL CAMINO REAL, SUITE 330, SUNNYVALE, CA, 94087, US

(73) Assignee: STATS CHIPPAC LTD., Singapore (SG)

(21) Appl. No.: 11/307,349

(22) Filed: Feb. 1, 2006

(51) Int. Cl. H01L 23/495

(52) U.S. Cl. 257/676

(57) ABSTRACT

An integrated circuit package system is provided. A leadframe is provided having a die-attach pad. Elevated buttons are formed on the top surface of the die-attach pad configured to support an IC die in an elevated position thereon.

### TECHNICAL FIELD

The present invention relates generally to leadframes for semiconductor packages, and more particularly to a system for heightened leadframe die-attach pad bondline thickness.

### BACKGROUND ART

An integrated circuit (“IC”) chip or die is a small electronic device formed on a semiconductor wafer, such as a silicon wafer. A leadframe is a metal frame that usually includes a paddle that supports an IC die after it has been cut from the wafer. The leadframe has lead fingers that provide external electrical connections for the IC die.

It is conventional in the electronics industry to encapsulate one or more semiconductor devices, such as IC dies, into semiconductor packages. These semiconductor packages protect the IC dies from environmental hazards and assist in electrically and mechanically attaching the IC dies to other electronic devices.

Commonly, such semiconductor packages include metal leadframes for supporting IC dies. An IC die is bonded to a die paddle region formed centrally on the leadframe. Bond wires electrically connect pads on the IC die to individual leads or lead fingers of the leadframe. That is, the IC die is attached to the die paddle, and then bonding pads of the IC die are connected to the lead fingers via wire bonding or flip die bumping to provide the external electrical connections. A hard plastic or epoxy encapsulating material (“encapsulant”) is then applied to form the exterior of the semiconductor package, covering the bond wires, the IC die, and (when present) other associated components.

Although the leadframe is the central supporting structure of the semiconductor package, only a portion of the leadframe is completely surrounded by the plastic encapsulant. Other portions of the leadframe are exposed externally or extend beyond the semiconductor package to electrically connect and physically support the semiconductor package externally.

Once the IC dies have been produced and encapsulated in semiconductor packages, as described above, they may be used in a wide variety of electronic devices. The number and variety of electronic devices utilizing semiconductor packages has grown dramatically in recent years.

Electronic devices that utilize semiconductor packages typically include a motherboard on which a significant number of such semiconductor packages are secured to provide multiple electronic functions. The semiconductor packages thus support the IC dies on the motherboards and transmit electrical signals from the IC dies to the motherboards.

Not only is the use of semiconductor packages widespread, but the ever-reducing size and cost of electronic devices puts continuous pressure on the need for smaller, less costly semiconductor packages. Also, for high bandwidth radio frequency (“RF”) devices and high operating frequency devices, there is a continuing need for shorter and shorter electrical paths inside semiconductor packages.

Thus, with continually increasing consumer demands and continuing progress in semiconductor technologies, electronic devices are manufactured in ever-increasing complexity, in ever-reduced sizes, and at ever-reduced costs. Accordingly, not only are IC dies more and more highly integrated, but semiconductor packages are more and more highly miniaturized, with ever-increasing levels of semiconductor package mounting density.

The requirement for such high performance, small size, thin semiconductor packages has resulted in the development of semiconductor packages having structures in which leads are exposed on the bottom of the encapsulant at respective lower surfaces thereof. Depending on the package type, the external leads may be used as-is, such as in a thin small outline package (“TSOP”), or further processed, such as by attaching spherical solder balls for a ball grid array (“BGA”). These various types of connection terminals allow the IC die to be electrically connected with other circuits, such as those on a printed circuit board (“PCB”).

With increasingly smaller die and package sizes, there is a pressing need for improved methods and structures to meet and match the ever-reducing external form factors (external package sizes, configurations, and thicknesses) while enabling existing, larger IC dies that are still being utilized to be used in newer products that demand these smaller form factors.

One known technique for incorporating larger IC dies into smaller semiconductor packages is to elevate the IC die slightly above the level of the die paddle. Such a configuration allows a larger IC die to be attached to a smaller die paddle with the periphery of the IC die overhanging the lead fingers of the leadframe. By allowing the larger IC die to overlap the inner ends of the lead fingers, the smaller leadframe can accept the larger IC die. This allows the older, larger IC die configuration to be utilized in a newer, smaller semiconductor package form factor than that for which the IC die was originally intended and configured.

One technique and configuration for raising or elevating the IC die above the die paddle is to use a thicker adhesive or bonding material to attach the IC die to the die paddle. The thicker adhesive causes the thickness of the bond line to be increased. The increased bondline thickness (“BLT”) elevates or raises the IC die and thereby allows the IC die to overhang the lead fingers without contacting the lead fingers.

One known solution for increasing the BLT of the IC die on the die paddle is to use an adhesive paste that is filled with small spacers, such as small spherical balls. The spacer-filled adhesive paste has a minimum thickness that is necessarily defined by the diameters of the solid spacers that fill the adhesive paste.

Unfortunately, there are a number of disadvantages associated with the use of spacer-filled adhesive paste to obtain a heightened BLT. For example, spacer-filled adhesive paste (e.g., epoxy paste) is more expensive than standard epoxy adhesive. Additionally, it is difficult to dispense a thick layer of filled epoxy paste in a uniform manner with the appropriate coverage shape for the area to be bonded, i.e., the area between the IC die and the die paddle. The consequent irregularities in the thickness, in the spread control, and in the epoxy coverage area cause potential overflow and contamination problems. This inconsistency in the epoxy coverage dimension and shape can also lead to potential delamination of the IC die from the die paddle and from the epoxy molding compound.

Another disadvantage results from the longer curing time that is required for spacer-filled epoxy, which causes longer assembly cycle times compared with standard epoxy. Yet another disadvantage of spacer-filled epoxy is that it is more difficult to dispense due to its higher viscosity. It also leads to difficulties with clogging of the dispensing nozzles due to the clustering effect of the spacers at the dispensing holes in the nozzles.

Thus, a need still remains for improved, more compact, and more economical leadframes that present smaller semiconductor package outline designs but that continue to accommodate existing larger IC die configurations and form factors. A particular need exists for effective and economical configurations and solutions that can provide heightened epoxy BLT enabling overhang die configurations without the disadvantages of spacer-filled epoxies.

In view of the ever-increasing commercial competitive pressures, increasing consumer expectations, and diminishing opportunities for meaningful product differentiation in the marketplace, it is increasingly critical that answers be found to these problems. Moreover, the ever-increasing need to save costs, improve efficiencies, improve performance, and meet such competitive pressures adds even greater urgency to the critical necessity that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit package system. A leadframe is provided having a die-attach pad. Elevated buttons are formed on the top surface of the die-attach pad configured to support an IC die in an elevated position thereon.

Certain embodiments of the invention have other advantages in addition to or in place of those mentioned above. The advantages will become apparent to those skilled in the art from a reading of the following detailed description when taken with reference to the accompanying drawings.

### BRIEF DESCRIPTION OF THE DRAWINGS

FIG. 1 is a cross-sectional view, taken as indicated by section line 1-1 in FIG. 2, of an embodiment of a leadframe according to the present invention;

FIG. 2 is an isometric view of the die-attach pad of the leadframe shown in FIG. 1;

FIG. 3 is a cross-sectional view of a leadframe button taken on line 3-3 in FIG. 2;

FIG. 4 is a cross-sectional view of a mechanical buttoning structure and process for forming buttons on the die-attach pad of the leadframe;

FIG. 5 is a view of the structure of FIG. 1 in the first stage of manufacture of a semiconductor package according to an embodiment of the present invention;

FIG. 6 is the structure of FIG. 5 following attachment of an IC die to the leadframe die-attach pad with a heightened leadframe die-attach pad bondline thickness in accordance with the present invention;

FIG. 7 is the structure of FIG. 6 following attachment of bond wires between the IC die and the lead fingers of the leadframe;

FIG. 8 is the structure of FIG. 7 formed into a semiconductor package following encapsulation;

FIG. 9 is a cross-sectional view, taken as indicated by section line 9-9 in FIG. 10, of another embodiment of a leadframe according to the present invention;

FIG. 10 is an isometric view of the die-attach pad of the leadframe shown in FIG. 9;

FIG. 11 is a cross-sectional view of a leadframe button taken on line 11-11 in FIG. 10;

FIG. 12 is a cross-sectional view depicting the formation of buttons on the die-attach pad of the leadframe of FIG. 9; and

FIG. 13 is a flow chart of a system for heightened leadframe die-attach pad bondline thickness in accordance with an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the invention are semi-diagrammatic and not to scale and, particularly, some of the dimensions are for the clarity of presentation and are shown greatly exaggerated in the drawing FIGs. Similarly, although the views in the drawings for ease of description generally show similar orientations, this depiction in the FIGs. is arbitrary for the most part. Generally, the invention can be operated in any orientation.

In addition, where multiple embodiments are disclosed and described having some features in common, for clarity and ease of illustration, description, and comprehension thereof, similar and like features one to another will ordinarily be described with like reference numerals.

For expository purposes, the term “horizontal” as used herein is defined as a plane parallel to the plane or surface of the leadframe die paddle, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane. The term “processing” as used herein includes deposition of material or photoresist, patterning, exposure, development, etching, cleaning, and/or removal of the material or photoresist as required in forming a described structure.

As will be explained more particularly hereinbelow, the present invention provides a heightened adhesive (e.g., epoxy) bondline thickness (“BLT”) using standard adhesives, thereby avoiding the numerous disadvantages of spacer-filled epoxy. It has been unexpectedly discovered that this can be accomplished with a leadframe configuration having protrusions (e.g., punch protrusions or etched protrusions) forming a button-studded die-attach pad (“DAP”). This configuration is advantageous for numerous package configurations, including quad leadless packages (“QLP”) and quad flat packages (“QFP”), and especially for QLP large-die overhang semiconductor packages.

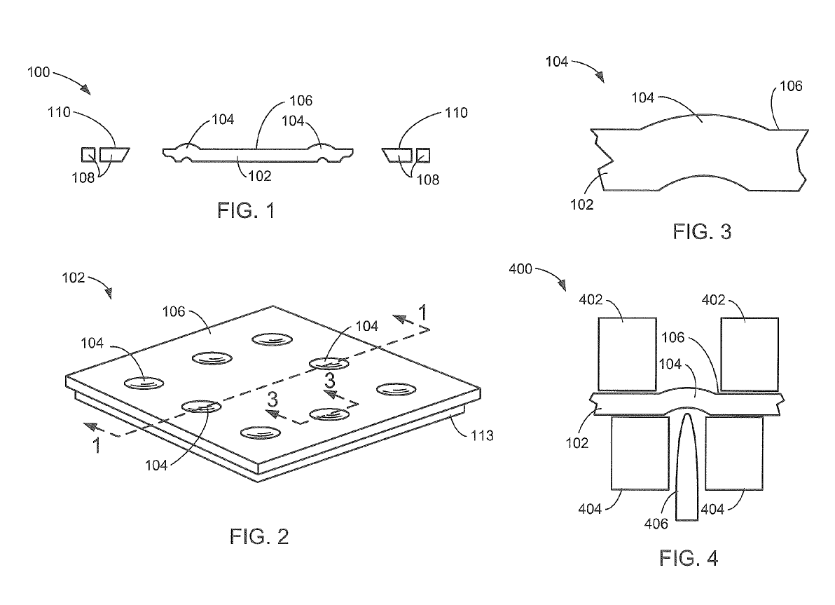

Referring now to FIG. 1, therein is shown a cross-sectional view of an embodiment of a leadframe 100 according to the present invention. The leadframe 100 includes a DAP 102 located generally centrally therein. (The cross-sectional view in FIG. 1 is indicated in FIG. 2 by section line 1-1 through the DAP 102.) Buttons 104, raised or elevated on the top surface 106 of the DAP 102, are formed thereon as described further hereinbelow. Lead fingers 108 generally surround the periphery of the DAP 102, as may be desired or required for the particular application at hand and as generally known in the art. In one embodiment, as shown in FIG. 1, the top surfaces 110 of the lead fingers 108 are at about the same height (i.e., roughly co-planar) as the top surface 106 of the DAP 102.

Referring now to FIG. 2, therein is shown an isometric view of the DAP 102. Based upon the disclosure, it will be understood that the positions of the buttons 104 are illustrative. In practice, the buttons 104 may vary in positions and numbers as deemed necessary, and are not limited just to the positions illustrated.

Referring now to FIG. 3, therein is shown a cross-sectional view of a button 104, taken on line 3-3 in FIG. 2.

Referring now to FIG. 4, therein is shown a cross-sectional view of a mechanical buttoning structure and process 400 for forming the buttons 104. Respective laterally spaced upper and lower clamps 402 and 404 grip and support the DAP 102 therebetween. A punch 406 is positioned between the laterally spaced lower clamps 404 and is actuated against the DAP 102 opposite the top surface 106 thereof to selectively push and shape the DAP 102 upwardly to create the configuration of the buttons 104. The buttons 104, formed in this manner, will then have the measurable physical characteristics of having been shaped with a mechanical buttoning process.

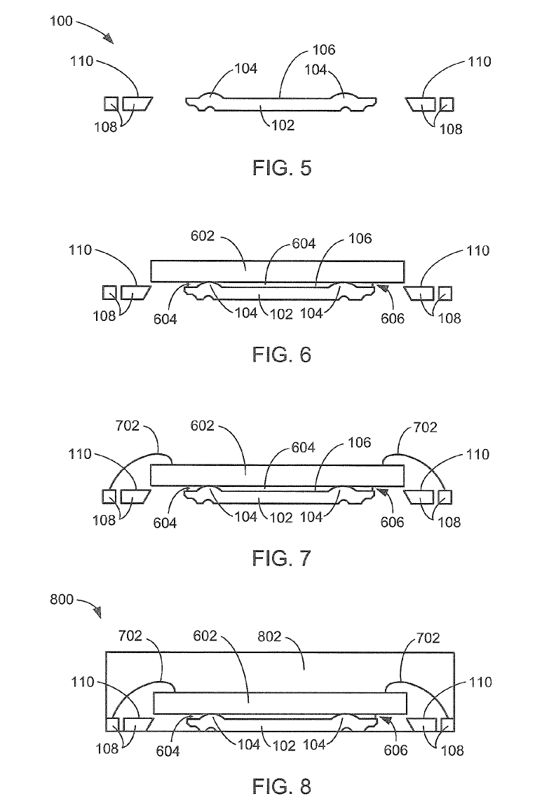

Referring now to FIG. 5, therein is shown the leadframe 100 in the first stage of the manufacture of a semiconductor package enabling an overhang IC die configuration.

Referring now to FIG. 6, therein is shown the structure of FIG. 5 following attachment of an IC die 602 to the DAP 102 by means of an adhesive 604. The buttons 104 are configured to support and hold the IC die 602 in an elevated position thereon spaced above the top surface 106 of the DAP 102. This provides an elevated or heightened leadframe die-attach pad BLT 606 that spaces the IC die 602 above the top surfaces 110 of the lead fingers 108, free of contact therewith. This allows the IC die 602 to be considerably larger than the DAP 102, extending well beyond the periphery thereof, and overhanging the lead fingers 108 without contacting them. Because the IC die 602 is elevated and spaced by the buttons 104 above the top surfaces 110 of the lead fingers 108 in this manner, the IC die 602 easily overhangs the lead fingers 108, as described, without risk of contact therewith. Thus, the IC die overhang configuration shown in FIG. 6 is readily and economically facilitated.

The IC die 602 is maintained at a precise and uniform spacing above the top surface 106 of the DAP 102 by virtue of the uniform shape and size of the buttons 104. Thus, no spacers are required in the adhesive material itself. Instead, the adhesive 604 may be a standard epoxy, free of spacers therein, thereby offering the advantages of lower cost, shorter curing time, lower viscosity, and so forth. These advantages result in faster, more economical, consistent, and reliable manufacturing. They also afford better finished product performance and durability (e.g., resistance to delamination).

Referring now to FIG. 7, therein is shown the structure of FIG. 6 following the attachment of bond wires 702 between the IC die 602 and the lead fingers 108.

Referring now to FIG. 8, therein is shown the structure of FIG. 7 formed into a semiconductor package 800 after being encapsulated in an encapsulant 802. The encapsulant 802 encapsulates the IC die 602, the bond wires 702, and portions of the lead fingers 108 and the DAP 102. The buttons 104 enable the semiconductor package 800 to support an overhang die configuration, as shown, that allows large-size dies to be readily accommodated and utilized in the smaller-sized semiconductor package 800.

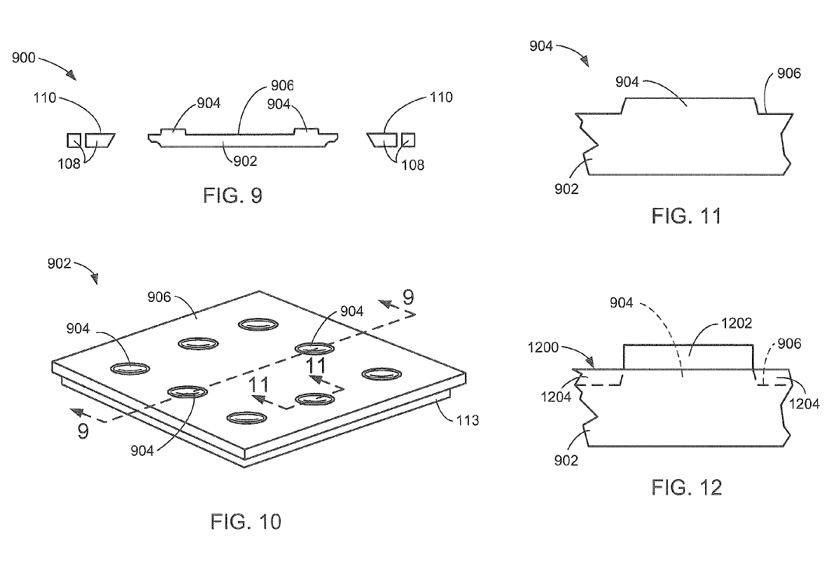

Referring now to FIG. 9, therein is shown a cross-sectional view of a leadframe 900 according to another embodiment of the present invention. The leadframe 900 includes a DAP 902 located generally centrally therein. (The cross-sectional view in FIG. 9 is indicated in FIG. 10 by section line 9-9 through the DAP 902.) Similar to the leadframe 100 (FIG. 1), the leadframe 900 includes buttons 904 raised or elevated on the top surface 906 of the DAP 902. Likewise, lead fingers 108 generally surround the periphery of the DAP 902, and in this embodiment, the top surfaces 110 of the lead fingers 108 are also at about the same height (i.e., roughly co-planar) as the top surface 906 of the DAP 902. However, unlike the leadframe 100, the buttons 904 are formed on the DAP 902 by an etching process rather than a mechanical buttoning process. More particularly, in the leadframe 900, the buttons are formed by etching the top of the DAP 902.

Referring now to FIG. 10, therein is shown an isometric view of the DAP 902. Based upon the disclosure, it will be understood that the positions of the buttons 904 are illustrative. In practice, the buttons 904 may vary in positions and numbers as deemed necessary, and are not limited just to the positions illustrated.

Referring now to FIG. 1, therein is shown a cross-sectional view of a button 904 taken on line 11-11 in FIG. 10.

Referring now to FIG. 12, therein is shown a cross-sectional view similar to FIG. 11 depicting the formation of the buttons 904 on the top surface 906 of the DAP 902. A leadframe precursor 1200 is initially provided having a thickness greater than the target thickness of the leadframe 900 (FIG. 9). A resist 1202 is patterned and formed in conventional manner on top of the leadframe precursor 1200 to define the buttons 904 that are to be formed, a button 904 being indicated in phantom in FIG. 12. A chemical half etching is then performed on the top of the DAP 902 to remove etched-out material 1204 above the surface contour of the top surface 906 of the DAP 902, thereby forming the buttons 904 thereon. The resist 1202 is then removed. The buttons 904, formed in this manner, will then have the measurable physical characteristics of having been formed by etching the top of the die-attach pad 902 to form the elevated buttons thereon.

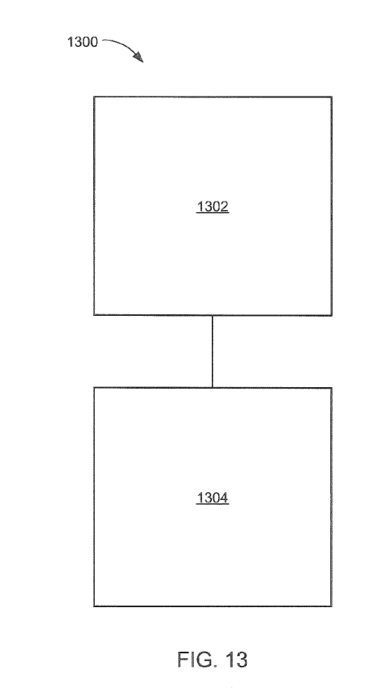

Referring now to FIG. 13, therein is shown a flow chart of an integrated circuit package system 1300 in accordance with an embodiment of the present invention. The system 1300 includes providing a leadframe having a die-attach pad, in a block 1302; and forming elevated buttons on the top surface of the die-attach pad configured to support an IC die in an elevated position thereon, in a block 1304.

It has been discovered that the present invention thus has numerous advantages.

A principle advantage that has been unexpectedly discovered is that the present invention readily, efficiently, and economically provides heightened adhesive BLT configurations and solutions using standard adhesives, such as standard epoxies, thereby avoiding the numerous disadvantages of spacer-filled epoxies.

Another advantage of the present invention is that it unexpectedly affords these advantages using an uncomplicated, readily configured and manufactured leadframe having a button-studded DAP.

Another advantage is that the present invention can be used effectively and beneficially for numerous package configurations, including QLP and QFP, and especially QLP large-die overhang semiconductor packages.

Yet another advantage is that package reliability and manufacturing yields are improved since standard epoxy adhesives can be used, thereby facilitating uniform dispensing coverage for the bonding area between the IC die and the die paddle.

Still another advantage is that the present invention provides more compact and more economical leadframes having smaller semiconductor package outline designs that nevertheless accommodate existing larger IC die configurations and form factors.

Yet another important advantage of the present invention is that it valuably supports and services the historical trend of reducing costs, simplifying systems, and increasing performance.

These and other valuable aspects of the present invention consequently further the state of the technology to at least the next level.

Thus, it has been discovered that the system for heightened leadframe DAP BLT of the present invention furnishes important and heretofore unknown and unavailable solutions, capabilities, and functional advantages for semiconductor device packaging, particularly of large-die configurations. The resulting processes and configurations are straightforward, cost-effective, uncomplicated, highly versatile and effective, can be implemented by adapting known technologies, and are thus readily suited for efficiently and economically manufacturing packaged semiconductor devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. An integrated circuit package system, comprising:
providing a leadframe having a die-attach pad; and
forming elevated buttons on the top surface of the die-attach pad configured to support an IC die in an elevated position thereon.

2. The system as claimed in claim 1 wherein forming elevated buttons on the top surface of the die-attach pad further comprises shaping the elevated buttons with a mechanical buttoning process.

3. The system as claimed in claim 1 wherein forming elevated buttons on the top surface of the die-attach pad further comprises etching the top of the die-attach pad to form the elevated buttons thereon.

4. The system as claimed in claim 1 further comprising attaching an IC die to the die-attach pad supported spaced by the elevated buttons above the top surface of the die-attach pad.

5. The system as claimed in claim 1 further comprising attaching an IC die to the die-attach pad with an adhesive free of spacers therein, the IC die being spaced from the die-attach pad by the elevated buttons thereon.

6. An integrated circuit package system, comprising:
providing a leadframe having a die-attach pad;
forming elevated buttons on the top surface of the die-attach pad configured to support an IC die in an elevated position thereon free of contact with lead fingers on the leadframe;
attaching an IC die to the die-attach pad supported by the elevated buttons spaced above the top surface of the die-attach pad; and attaching bond wires between the IC die and lead fingers on the leadframe.

7. The system as claimed in claim 6 wherein forming elevated buttons on the top surface of the die-attach pad further comprises shaping the elevated buttons with a mechanical buttoning process.

8. The system as claimed in claim 6 wherein forming elevated buttons on the top surface of the die-attach pad further comprises forming the elevated buttons using an etch of the top surface of the die-attach pad to etch the top of the die-attach pad to form the elevated buttons thereon.

9. The system as claimed in claim 6 wherein attaching an IC die to the die-attach pad further comprises attaching an IC die to the die-attach pad with an epoxy free of spacers therein, the IC die being spaced from the die-attach pad by the elevated buttons thereon.

10. The system as claimed in claim 6 further comprising encapsulating the IC die, the bond wires, and at least portions of the lead fingers and the die-attach pad in an encapsulant to form a semiconductor package.

11. An integrated circuit package system, comprising:
a leadframe having a die-attach pad; and
elevated buttons on the top surface of the die-attach pad configured to support an IC die in an elevated position thereon.

12. The system as claimed in claim 11 wherein the elevated buttons on the top surface of the die-attach pad further comprise buttons having the characteristics of having been shaped with a mechanical buttoning process.

13. The system as claimed in claim 11 wherein the elevated buttons on the top surface of the die-attach pad further comprise buttons having the characteristics of having been formed by etching the top of the die-attach pad to form the elevated buttons thereon.

14. The system as claimed in claim 11 further comprising an IC die attached to the die-attach pad supported spaced by the elevated buttons above the top surface of the die-attach pad.

15. The system as claimed in claim 11 further comprising:
an IC die;
an adhesive, free of spacers therein, attaching the IC die to the die-attach pad; and
the IC die being spaced from the die-attach pad by the elevated buttons thereon.

16. An integrated circuit package system, comprising:
a leadframe having lead fingers and a die-attach pad;
elevated buttons on the top surface of the die-attach pad configured to support an IC die in an elevated position thereon free of contact with the lead fingers;
an IC die attached to the die-attach pad supported by the elevated buttons spaced above the top surface of the die-attach pad; and
bond wires attached between the IC die and the lead fingers on the leadframe.

17. The system as claimed in claim 16 wherein the elevated buttons on the top surface of the die-attach pad further comprise buttons having the characteristics of having been shaped with a mechanical buttoning process.

18. The system as claimed in claim 16 wherein the elevated buttons on the top surface of the die-attach pad further comprise buttons having the characteristics of having been formed by etching the top of the die-attach pad to form the elevated buttons thereon.

19. The system as claimed in claim 16 further comprising an epoxy attaching the IC die to the die-attach pad, the epoxy being free of spacers therein, and the IC die being spaced from the die-attach pad by the elevated buttons thereon.

20. The system as claimed in claim 16 further comprising an encapsulant encapsulating the IC die, the bond wires, and at least portions of the lead fingers and the die-attach pad to form a semiconductor package.
